(19) United States
(12) Patent Application Publication
(10) Pub. No.: US 2012/0234379 A1
(43) Pub. Date: Sep. 20, 2012

(54) SOLAR CELL MODULE AND METHOD FOR MANUFACTURING THE SAME

(75) Inventor: Masaharu TAKENAKA, Kishiwada-shi (JP)

(73) Assignee: SANYO ELECTRIC CO., LTD., Moriguchi-shi (JP)

(21) Appl. No.: 13/483,169

(22) Filed: May 30, 2012

Related U.S. Application Data
(63) Continuation of application No. PCT/JP2010/071284, filed on Nov. 29, 2010.

(30) Foreign Application Priority Data
Nov. 30, 2009 (JP) 2009-271226

(51) Int. Cl. H01L 31/048; H01L 31/18

(52) U.S. Cl. 136/251; 29/890.033

(57) ABSTRACT

The shape of a sealing material between a frame and a solar cell panel in a drainage notch is regulated so that rainwater, etc., is smoothly drained from the drainage notch. A frame of a solar cell module is provided with: a main body; a fitting part disposed on the top of the main body and receiving the peripheral edge portion of the solar cell panel; and a drainage notch formed by cutting out the fitting part from a position near a front member of the solar cell panel to a position below the front member. A sealing material in the notch is shaped so as to cover at least the peripheral edge portion of the solar cell panel and an exposed top part of the main body of the frame, but not to exceed the front member of the solar cell panel.

### CROSS-REFERENCES TO RELATED APPLICATIONS

This application is based on International Application PCT/JP2010/071284 which claims priority on the basis of Japanese Patent Application No. 2009-271226.

### TECHNICAL FIELD

This invention relates to a solar cell module and a method for manufacturing the solar cell module, and more particularly to a solar cell module with a frame.

### BACKGROUND ART

In recent years, solar cell modules, which extract electric power via photoelectric conversion of sunlight, have been widely utilized. In order for solar cell modules to bear various environmental burdens, such as snow loads and wind pressure, an aluminum frame is attached along the peripheral edge portion of a solar cell panel including solar cells.

The frame, in addition to a front member, imparts strength to the solar cell modules, which eliminates the necessity to increase the thickness of the front member to make large solar cell modules. Consequently, the solar cell modules do not increase in weight and can be handled readily. Thinning the thickness of the front member increases the amount of light passing through the front member, thereby improving power generation efficiency.

By the way, there is a level difference between the aforementioned frame and front member of the solar cell panel. After rainfall, rainwater may collect in the level difference region. For the purpose of preventing rainwater from pooling on the front member after rainfall, solar cell modules have been proposed that are provided with a frame with a drainage notch (see, e.g., PTL 1).

FIG. 15 is a cross-sectional view of the solar cell module including a solar cell panel attached to a frame with a drainage notch. A commonly used solar cell panel 10 includes a front member 12, such as a clear glass board, solar cells 11 encapsulated by an encapsulant 14, such as ethylene-vinyl acetate, and a back member 13, which is a sandwich type vinyl fluoride film with an aluminum foil interposed therein, to support the back side of the solar cell panel 10.

As described above, a frame 20 is attached to the peripheral edge portion of the solar cell panel 10 to impart mechanical strength and the frame 20 is provided with a fitting part 22 that receives the peripheral edge portion of the solar cell panel 10. In order to more reliably ensure the fit between the solar cell panel 10 and frame 20, a sealing material 60, such as silicone, is used to fix the peripheral edge portion of the solar cell panel 10 with the frame 20. In addition, a drainage notch 28 is formed in the fitting part 22 of the frame 20 to drain rainwater.

### CITATION LIST

### Patent Literature

PTL 1: Japanese Unexamined Utility Model Application Publication No. 1994-17257

### SUMMARY OF INVENTION

### Technical Problem

However, when the solar cell panel 10 is attached to the aforementioned frame 20 having the drainage notch 28 with the sealing material, the sealing material 60 that is applied to the inner side of the frame 20 may be squeezed out from the notch 28 onto the front member 12 as shown in FIG. 15. The squeezed sealing material 60 causes water to flow backward, as indicated by an arrow in FIG. 15, and therefore the notch 28 cannot properly drain water.

The present invention is made to solve the problem and has an objective for regulating the shape of the sealing material, between the frame and solar cell panel, in the drainage notch to smoothly drain rainwater or the like from the drainage notch.

### Solution to Problem

The present invention is directed to a solar cell module in which a frame is attached to the peripheral edge portion of a solar cell panel. The frame includes: a main body; a fitting part provided on the top of the main body and configured to receive the peripheral edge portion of the solar cell panel; and a drainage notch formed by cutting out the fitting part from a position near a front member of the solar cell panel to a position below the front member. A sealing material in the notch is shaped so as to cover at least the peripheral edge portion of the solar cell panel and an exposed top part of the main body of the frame, but not to exceed the front member of the solar cell panel.

The solar cell panel can be fitted in the fitting part with the sealing material therebetween. The sealing material is shaped into a tapered triangle in cross section that widens from below the upper surface of front member of the solar cell panel toward an edge of the frame.

The present invention is directed to a method for manufacturing a solar cell module including: a solar cell panel; a frame having a main body, a fitting part disposed on the top of the main body and receiving the peripheral edge portion of the solar cell panel, a drainage notch formed by cutting out the fitting part from a position near a front member of the solar cell panel to a position below the front member. In the method, the notch is clamped by a jig regulating the shape of a sealing material formed in the notch, the peripheral edge portion of the solar cell panel is inserted into the fitting part after the sealing material is applied in the fitting part, the shape of the sealing material squeezed out to the notch is regulated by the jig, and the sealing material in the notch is shaped so as to cover at least the peripheral edge portion of the solar cell panel and an exposed upper part of the main body of the frame, but not to exceed the front member of the solar cell panel.

The jig includes a lower projection to abut on the bottom of the main body of the frame, an upper projection to be fitted into the notch and having a shape similar to the upper portion of the fitting part, and a tapered face extending downwardly from a part of the upper projection where the peripheral edge portion of the solar cell panel is positioned toward an edge of the main body of the frame.

### Advantageous Effects of Invention

This invention allows water to flow from the notch without obstruction of the sealing material and prevents water having reached the notch from entering in between the solar cell panel and frame.

### BRIEF DESCRIPTION OF DRAWINGS

FIG. 1 is a plan view of a solar cell module according to the first embodiment of the invention.

FIG. 2 is a perspective view showing a relevant part of the solar cell module according to the first embodiment of the invention.

FIG. 3 is a perspective view showing a relevant part of the solar cell module according to the first embodiment of the invention.

FIG. 4 is a cross-sectional view showing a relevant part of the solar cell module according to the first embodiment of the invention.

FIG. 5 is a cross-sectional view showing a relevant part of the solar cell module according to the first embodiment of the invention.

FIG. 6 is a plan view showing assembly of a frame of the solar cell module according to the first embodiment of the invention.

FIG. 7 is an exploded perspective view showing assembly of the frame of the solar cell module according to the first embodiment of the invention.

FIG. 8 is a perspective view showing the assembled frame of the solar cell module according to the first embodiment of the invention.

FIG. 9 is a perspective view showing a method for manufacturing the solar cell module and particularly how to clamp jigs to the frame.

FIG. 10 is a cross-sectional view showing the method for manufacturing the solar cell module and particularly how to insert the solar cell panel into the frame.

FIG. 11 is a cross-sectional view showing the method for manufacturing the solar cell module and particularly how to insert the solar cell panel into a notch of the frame.

FIG. 12 is a perspective view showing the method for manufacturing the solar cell module and particularly the jigs clamping the frame.

FIG. 13 is a plan view of a solar cell module according to the second embodiment of the invention.

FIG. 14 is a cross-sectional view showing a relevant part of the solar cell module according to the second embodiment of the invention.

FIG. 15 is a cross-sectional view of the solar cell module including a solar cell panel attached to a frame having a drainage notch.

### DESCRIPTION OF EMBODIMENTS

With reference to the drawings, embodiments of the present invention will be described in detail. Through the drawings, like components are denoted by like numerals and, to avoid being redundant, will not be further explained.

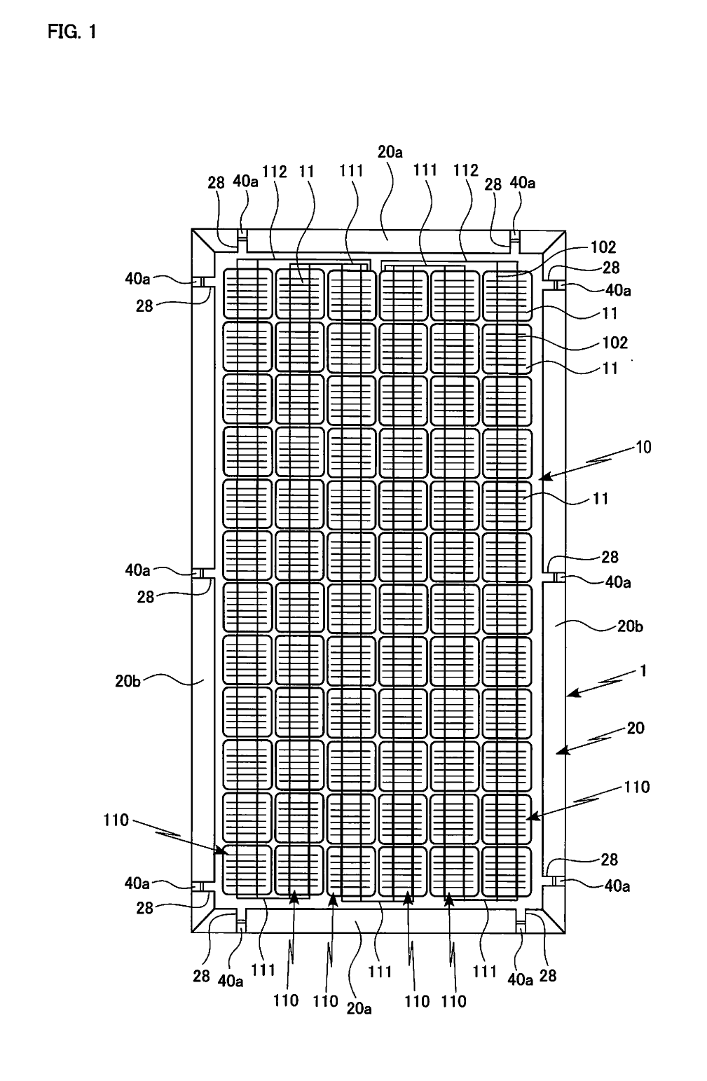

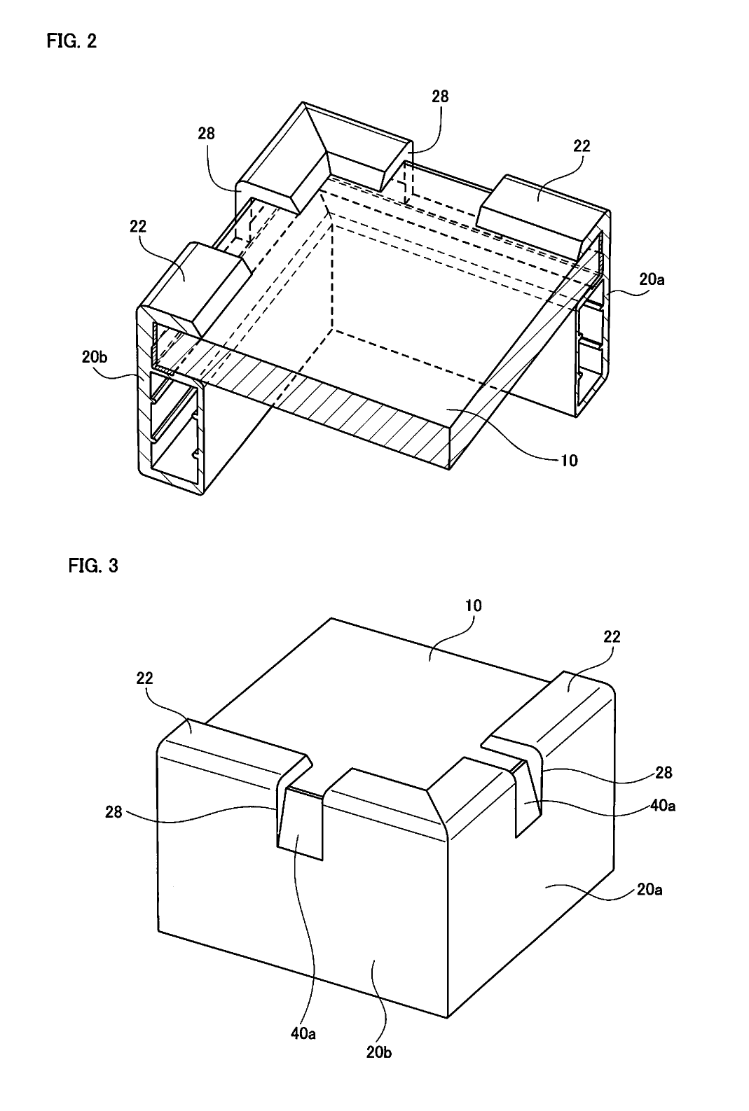

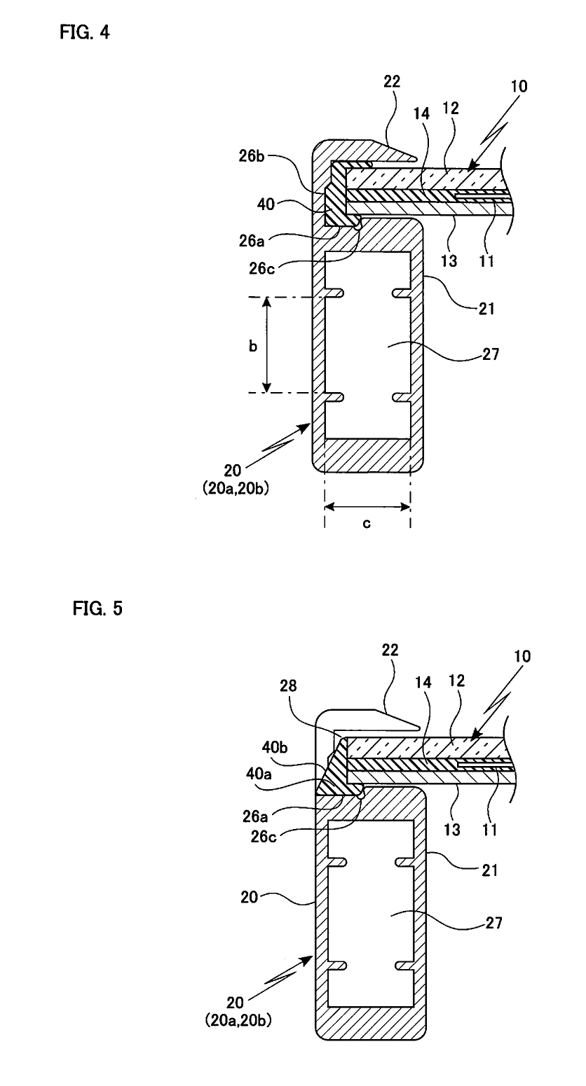

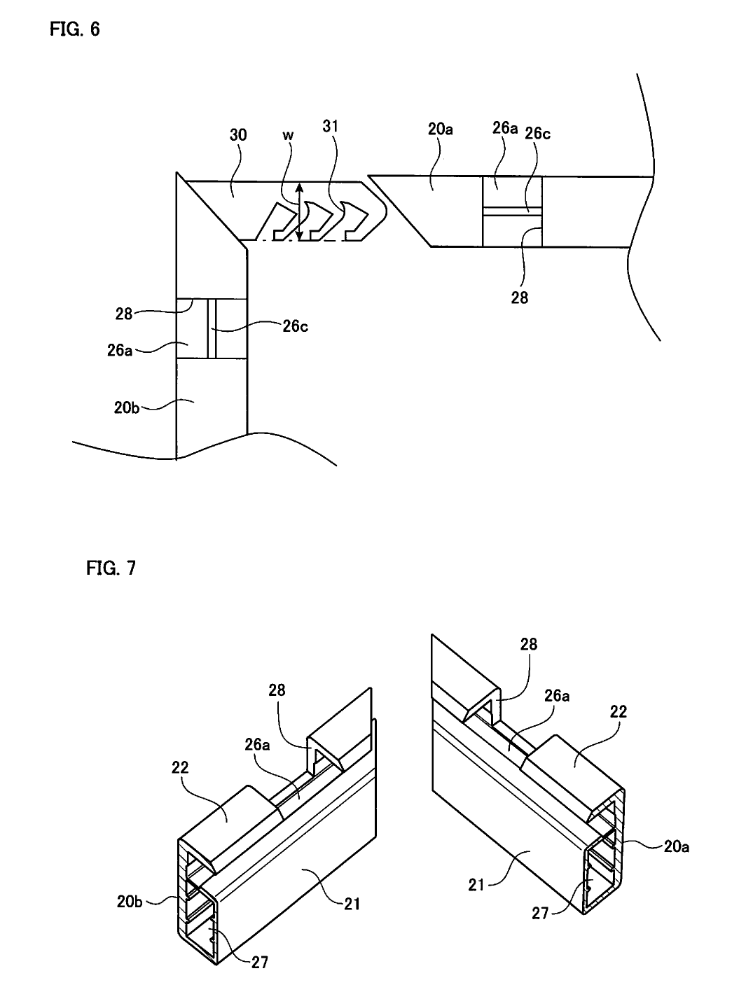

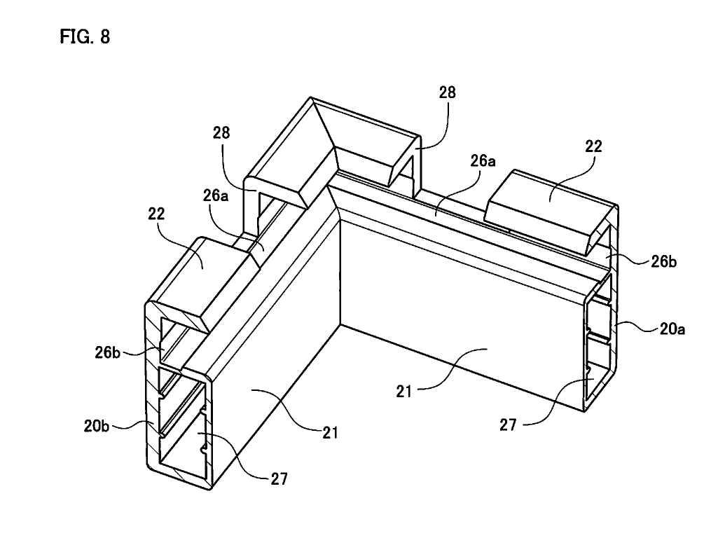

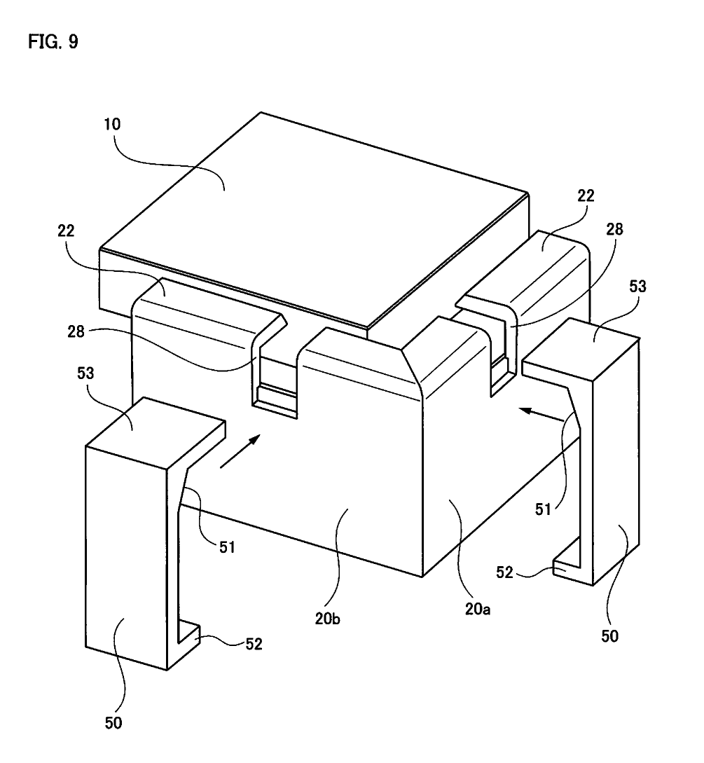

FIG. 1 is a plan view of a solar cell module according to the first embodiment of the invention; FIGS. 2 and 3 are perspective views showing a relevant part of the solar cell module; FIGS. 4 and 5 are cross-sectional views showing a relevant part of the solar cell module; FIG. 6 is a plan view showing assembly of a frame of the solar cell module; FIG. 7 is an exploded perspective view showing assembly of the frame of the solar cell module; FIG. 8 is a perspective view of the assembled frame of the solar cell module.

As shown in FIG. 1, the solar cell module 1 according to the invention includes a solar cell panel 10 and a frame 20 that protects the solar cell panel 10. The frame 20 includes a pair of first frames 20a disposed along the shorter sides of the solar cell panel 10 and a pair of second frames 20b disposed along the longer sides of the solar cell panel 10.

As shown in FIGS. 6 to 8, the first frames 20a and second frames 20b are coupled to each other at their ends in the longitudinal direction. The frame 20 formed by alternately coupling the first frames 20a and second frames 20b protects the solar cell panel 10. Thus configured solar cell module 1 is used after being attached on a mounting base (not shown) or the like. For example, the length of the first frame 20a is approximately 800 mm, and the length of the second frame 20b is approximately 1500 mm to 1600 mm.

The solar cell panel 10 is roughly rectangular in planar view. The solar cell panel 10, as shown in FIGS. 1 to 5, includes a plurality of solar cells 11 electrically interconnected with ribbons 102, which are made from a conductive material such as a copper foil, a transparent front member 12, and a back member 13 made of a weatherproof film. The solar cells 11 are sealed with a transparent encapsulant 14, such as excellent weather-resistant and moisture-resistant EVA (ethylene vinylacetate), between the front member 12 and back member 13.

The plurality of solar cells 11 connected with the ribbons 102 in series make up a string 110 as a unit of solar cells 11. The strings 110 and 110 are connected with a connecting wire, so-called a bus ribbon 111. In addition, end ribbons 112 are connected to extract outputs from the solar cells 11 to external equipment.

The solar cell 11 is, for example, a crystalline semiconductor made of monocrystalline silicon, polycrystalline silicon or the like, having a thickness of approximately 0.15 mm in the form of roughly a square of 100 mm for a side; however the present invention is not limited thereto, and other types of solar cell can be used.

In the solar cell 11, for example, there are an n-type region, a p-type region and a junction to form an electric field for carrier separation at the interface between the n-type region and the p-type region. An exemplary solar cell is a so-called hetero-junction with intrinsic thin layer solar cell capable of reducing defects at the interface and improving the hetero junction interface characteristics by interposing a substantially intrinsic amorphous silicon layer between a monocrystalline silicon substrate and an amorphous silicon layer.

The front member 12 is a light-transmissive plate through which light can pass to the solar cells 11. The front member 12 may be a glass plate made of clear glass, reinforced glass and heat-reflective glass or other types of glass, or a synthetic resin plate made of polycarbonate resin or other types of resin.

The back member 13 is made of Poly-Vinyl Fluoride (PVF), polyethylene terephthalate (PET) or Polyethylene naphthalate (PEN), a lamination thereof, or a PET film with an aluminum foil interposed.

The peripheral edge portion of the solar cell panel 10 is fitted in the frame 20, made of aluminum or the like, with a sealing material 40. The sealing material 40 can be silicone resin, butyl rubber, epoxy-based resin or urethane-based resin. In this embodiment, silicone resin is used as the sealing material 40.

If needed, a terminal box (not shown) is provided, for example, on a surface of the back member 13.

As shown in FIGS. 6 to 8, the first frames 20a and second frames 20b making up the frame 20 are made of, for example, aluminum, iron, stainless steel, resin or the like by extrusion processing or other methods. Each of these frames 20a, 20b includes a hollow main body 21 and a U-shaped cross-section fitting part 22 disposed on the top of the main body 21. The peripheral edge portion of the solar cell panel 10 is inserted into the fitting part 22 with the sealing material, such as silicone resin. On the upper face of the main body 21, which is a support portion positioned at the lower side of the fitting part 22, formed is a recess 26a to which the sealing material is applied. On a wall of the fitting part 22 standing perpendicular to the recess 26a, formed is a recess 26b to which the sealing material is applied. In addition, a groove 26c for storing the sealing material is formed so as to connect with the recess 26a of the main body 21.

The frames 20a, 20b have rectangular attaching portions 27 at their corners to receive a press-fitted corner piece 30.

The corner piece 30 press-fitted into the attaching portion 27 is made of aluminum and has a hook portion 31 as shown in FIG. 6. As shown in FIGS. 4 and 6, the hook portion 31 has a width (w) slightly wider than the width (c) of the rectangular attaching portion 27 and a height equal to or slightly less than the height (b) of the attaching portion 27.

As shown in FIGS. 6 to 8, connection of the frames 20a, 20b is carried out by press-fitting one hook portion 31 of a corner piece 30 into an attaching portion 27 of a frame 20b (20a) and securing the corner piece 30 with pressure, and subsequently, press-fitting an other hook portion 31 of the corner piece 30 into an attaching portion 27 of a frame 20a (20b), thereby securely connecting the frames 20a and 20b.

The frames 20a, 20b have drainage notches 28 formed by partially cutting out the fitting part 22 to drain water stored on the front member 12 of the solar cell module 1. The number of the notches 28 is appropriately chosen according to the size of the solar cell module 1.

In this embodiment, as shown in FIG. 1, the frames 20a, 20b have a notch 28 at the opposite ends, respectively, near the corner regions where are likely to store water. In addition, the frames 20b disposed on the longer sides of the solar cell panel 10 have a notch 28 in the middle thereof, respectively. Accordingly, the frames 20a on the shorter sides have one notch 28 at the opposite ends, respectively, near the corner regions, in other words, each of the frames 20a has two notches 28 in total.

The frames 20b on the longer sides have one notch 28 at the opposite ends and one in the middle, in other words, each of the frames 20b has three notches 28 in total.

The notch 28 is formed by cutting out the frame so as to have a width within the range from approximately 5 mm to 10 mm and a height to be lower than the front member 12 of the solar cell panel 10 fitted in the frame 20. In this embodiment, the notch 28 is formed from the top end face of the vertically raised wall of the fitting part 22 to the recess 26a.

In addition, the notches 28 formed at the corner regions are positioned approximately 15 mm to 20 mm away from the corners.

Silicone resin, as a sealing material 40, is applied by a dispenser to the recesses 26a, 26b formed in the fitting part 22 of the frames 20a, 20b. Then, the peripheral edge portion of the solar cell panel 10 is inserted into the fitting part 22 of the frames 20a, 20b to attach the frames 20a, 20b to the solar cell panel 10.

The silicone resin is squeezed out to the notch's opening that positionally corresponds to the wall of the fitting part 22 of the frames 20a, 20b from the ambient of the notch 28. In this invention, the sealing material in the notch 28 is shaped so that the sealing material does not block water flowing from the front member 12 of the solar cell module 1 and the water drained from the notch 28 does not enter in between the solar cell panel 10 and frame 20.

Therefore, the sealing material 40a present in the notch 28 covers at least the peripheral edge portion of the solar cell panel 10 and an exposed top part of the main body 21 of the frames 20a, 20b, but does not exceed the front member 12 of the solar cell panel 10. In addition, the sealing material 40a covers, on the peripheral edge portion of the solar cell panel 10, at least the peripheral edge portion of the back member 13 and the periphery of the encapsulant 14 and at least a part of the peripheral edge portion of the front member 12.

In this embodiment, as shown in FIGS. 3 to 5, the sealing material 40a formed in the notch 28 is shaped into a tapered triangle in cross section that covers the recess 26a formed in the main body 21 and widens from slightly below the upper surface of the front member 12 of the solar cell panel 10 toward an edge of the frames 20a, 20b. On a plane of the sealing material 40a formed from the frame 20a (20b) side to the solar cell panel 10 side, formed is a tapered surface 40b that extends from the upper side to the lower side of the fitting part 22.

The sealing material 40 that is applied to areas of fitting part 22 where the notch 28 is not formed is squeezed to the upper surface of the front member 12, as shown in FIG. 4, and reliably seals and firmly fixes the peripheral edge portion of the solar cell panel 10 in the fitting part 22.

As described above, shaping the sealing material 40a in the notch 28 so as not to exceed the front member 12 of the solar cell panel 10, but to cover the recess 26a formed in the main body 21 can prevent water drained from the notch 28 from entering in between the solar cell panel 10 and frame 20. The tapered surface 40b of the sealing material 40a allows water to be smoothly drained from the notch 28.

In addition, the sealing material 40a is shaped to cover the peripheral edge portion of the encapsulant 14, thereby preventing water drained from the notch 28 from intruding the encapsulant 14. This can also prevent the output characteristic degradation of the solar cells 11 sealed inside the encapsulant 14 due to intrusion of the water.

In addition, the sealing material 40a is shaped to cover the peripheral edge portion of the back member 13, thereby preventing the peripheral edge portion of the back member 13 from being exposed to water. Therefore, deterioration of the back member 13 caused by water intrusion can be prevented.

Furthermore, using the sealing material 40a of a similar color as the frame 20 makes the notch 28 inconspicuous, which is favorable in terms of design.

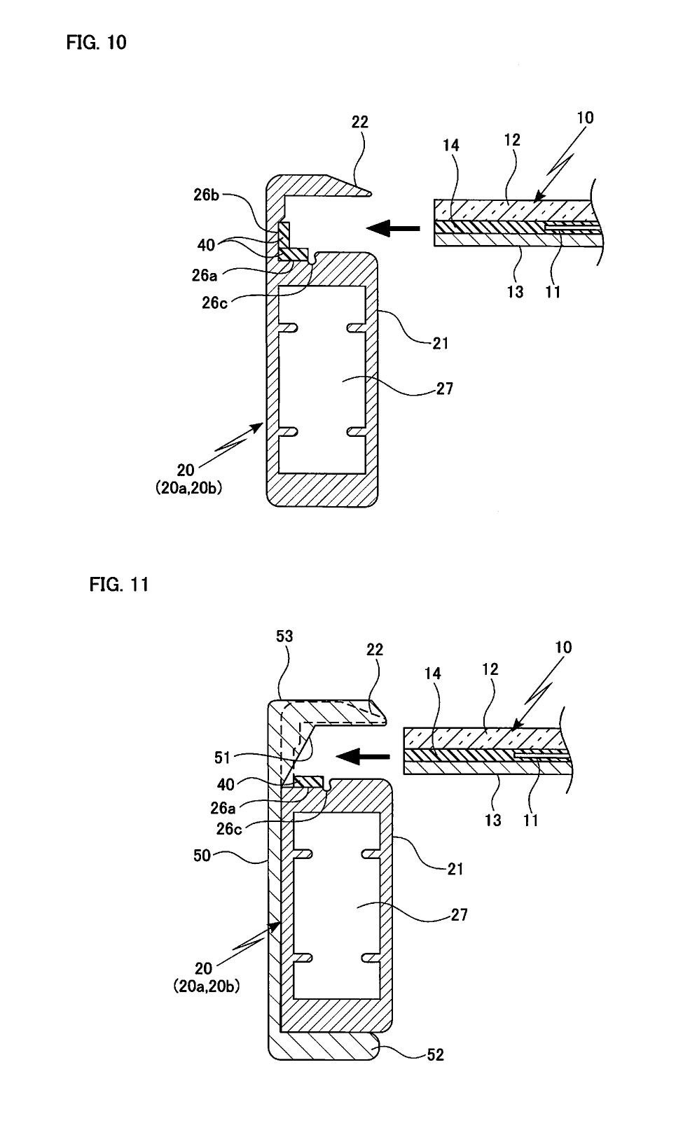

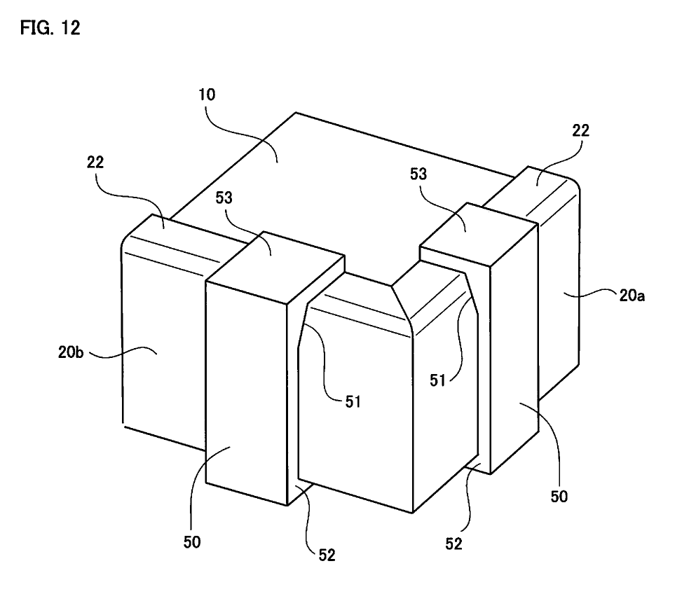

With reference to the drawings, description will be made about a method for shaping the sealing material 40a to be provided in the notch 28 into a desirable shape without cleaning the appearance. FIG. 9 is a perspective view showing the method for manufacturing the solar cell module according to the present invention and particularly how to clamp jigs to the frame; FIG. 10 is a cross-sectional view showing the method for manufacturing the solar cell module of the invention and particularly how to insert the solar cell panel into the frame; FIG. 11 is a cross-sectional view showing the method for manufacturing the solar cell module of the invention and particularly how to insert the solar cell panel into a notch of the frame; and FIG. 12 is a perspective view showing the method for manufacturing the solar cell module of the invention and particularly the jigs clamping the frame.

As shown in FIGS. 9, 11 and 12, jigs 50 are attached to the notches 28 to regulate the shape of the sealing material. Each jig 50 is slid on the bottom of the main body 21 of the frame 20 and the upper surface of the fitting part 22 to clamp the frame 20. The jig 50 includes a lower projection 52 that abuts on the bottom of the main body 21 and an upper projection 53 that fits in the notch 28 and has a shape similar to the upper portion of the fitting part 22. Also, the jig 50 has a tapered face 51 that extends downwardly from a part of the upper projection 53 where the peripheral edge portion of the solar cell panel 10 is positioned toward an end of the recess 26a of the frame 20.

Attachment of the frame 20 to the solar cell panel 10 starts with inserting the jigs 50 into the notches 28 of the frames 20a, 20b as shown in FIGS. 11 and 12 and then fixing the jigs 50 so that the tapered faces 51 for regulating the shape of the sealing material face the notches 28.

Subsequently, silicone resin, serving as the sealing material 40, is applied by a dispenser to the recesses 26a, 26b in the fitting parts 22 of the frames 20a, 20b. The amount of the applied silicone resin is 32 g/m. As shown in FIG. 10, the sealing material 40 is applied to the recesses 26a, 26b of the fitting part 22 where the notches 28 are not formed, while the sealing material 40 is applied to the recess 26a of the fitting part 22 where the notches 28 are formed as shown in FIG. 11.

Then, the peripheral edge portion of the solar cell panel 10 is inserted into the fitting part 22. Insertion of the solar cell panel 10 squeezes the sealing material 40 applied inside the fitting part 22 out onto the front member 12 of the solar cell panel 10 as shown in FIG. 4, thereby reliably sealing and firmly fixing the peripheral edge portion of the solar cell panel 10 in the fitting part 22.

On the other hand, the sealing material 40 including silicone resin is squeezed out from the ambient of the notch 28 to the notch's opening that positionally corresponds to the wall of the fitting part 22. The shape of the squeezed sealing material is regulated by the jigs 50 so that the sealing material 40a is tapered from slightly below the upper surface of the front member 12 of the solar cell panel 10 toward the ends of the frames 20a, 20b.

After the sealing material is cured, the jigs 50 are taken off from the frames 20a, 20b as shown in FIG. 5, thereby forming the sealing material 40a whose shape is regulated by the jigs 50 in the notches 28. As described above, the use of the jigs 50 enables formation of tapered sealing material 40a that covers the recess 26a formed in the main body 21 and widens from slightly below the upper surface of the front member 12 of the solar cell panel 10 toward the ends of the frames 20a, 20b without cleaning the appearance.

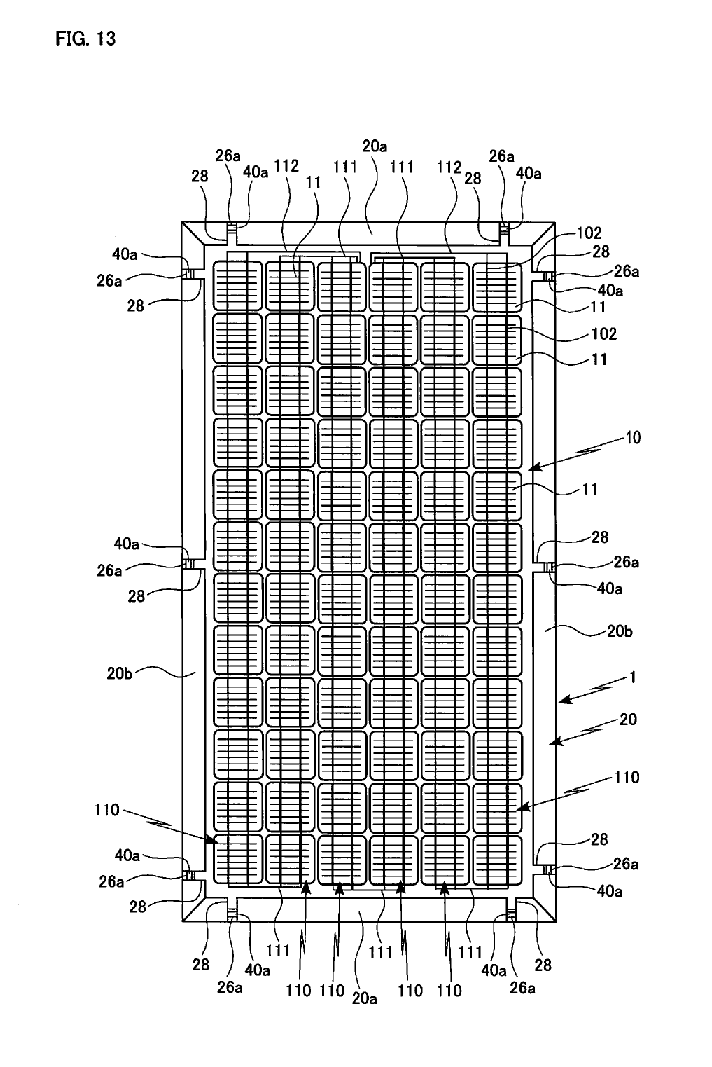

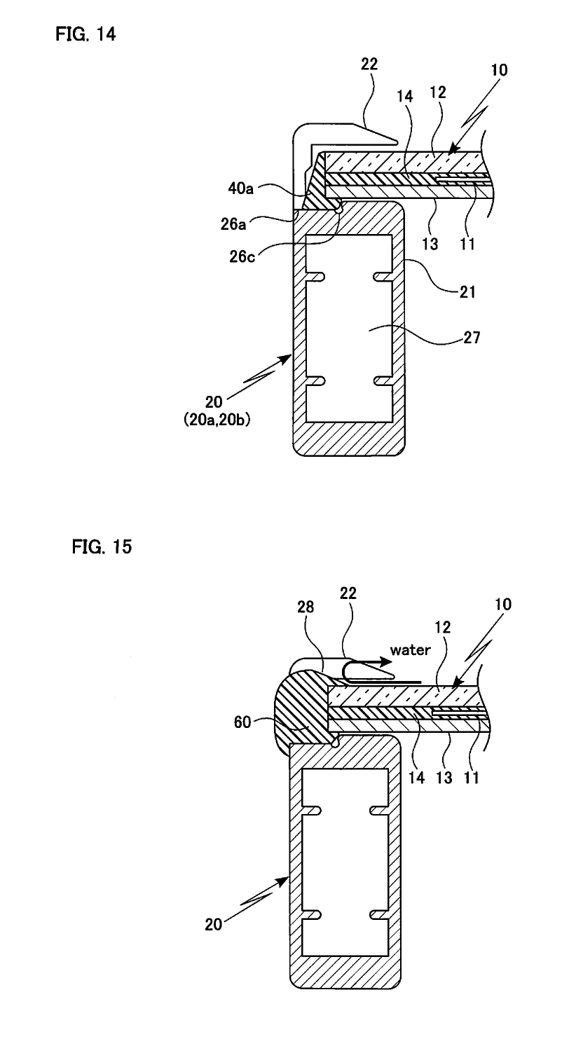

With reference to FIGS. 13 and 14, the second embodiment according to the present invention will be described. FIG. 13 is a plan view of a solar cell module according to the second embodiment of the invention, and FIG. 14 is a cross-sectional view showing a relevant part of the solar cell module.

In the first embodiment, the sealing material 40a applied to the notches 28 is shaped so as to cover the peripheral edge of the main body 21 of the frame 20a (20b) and to hide the surface of the recess 26a.

On the contrary, the sealing material 40a in the second embodiment is shaped so as not to reach the peripheral edge of the main body 21 of the frame 20a (20b) to expose a part of the recess 26a.

Such shaped sealing material 40a can be obtained by using jigs that regulates the sealing material 40a so as not to reach the peripheral edge of the main body 21 of the frame 20a (20b) to leave a part of the recess 26a exposed.

Shaping the sealing material 40a so as not to reach the peripheral edge of the frame 20a (20b) can reliably prevent the sealing material from being squeezed to the peripheral edge of the frame 20a (20b), and therefore can eliminate the need for most cleaning work on a side of the main body 21 of the frame 20a (20b).

Although all of the first frames 20a and second frames 20b are configured to have notches 28, respectively, in the first and second embodiments, it is acceptable to provide the notch 28 to at least one of the first frames 20a and second frames 20b. In addition, there can be various possibilities in the number and position of the notches 28 to be formed in the frames 20a (20b).

It should be understood that the embodiments disclosed herein are to be taken as examples in every point and are not limited. The scope of the present invention is defined not by the above described embodiments, but by the appended claims. All changes that fall within means and bounds of the claims, or equivalence of such means and bounds are intended to be embraced by the claims.

### REFERENCE SIGNS LIST

10 solar cell module body
11 solar cell
20 frame
20a first frame
20b second frame
21 frame main body
22 fitting part
27 attaching portion
28 notch
30 corner piece
31 hook portion
40, 40a sealing material

1. A solar cell module in which a frame is attached to a peripheral edge portion of a solar cell panel, wherein
the frame comprises:
a main body;
a fitting part provided on the top of the main body and configured to receive the peripheral edge portion of the solar cell panel; and
a drainage notch formed by cutting out the fitting part from a position near a front member of the solar cell panel to a position below the front member, and
a sealing material in the notch is shaped so as to cover at least the peripheral edge portion of the solar cell panel and an exposed top part of the main body of the frame, but not to exceed the front member of the solar cell panel.

2. The solar cell module according to claim 1, wherein the solar cell panel is fitted in the fitting part with the sealing material therebetween.

3. The solar cell module according to claim 1, wherein the sealing material is shaped into a tapered triangle in cross section widening from below the front member of the solar cell panel toward an edge of the frame.

4. A method for manufacturing a solar cell module,
the solar cell module including:
a solar cell panel; and
a frame having a main body, a fitting part disposed on the top of the main body and receiving a peripheral edge portion of the solar cell panel, a drainage notch formed by cutting out the fitting part from a position near a front member of the solar cell panel to a position below the front member, comprising:
clamping a jig on the notch, the jig being used for regulating a sealing material to be applied to the notch;
applying the sealing material in the fitting part; and
inserting the peripheral edge portion of the solar cell panel into the fitting part; wherein
the shape of the sealing material squeezed out to the notch is regulated by the jig, and
the sealing material in the notch is shaped so as to cover at least the peripheral edge portion of the solar cell panel and an exposed upper part of the main body of the frame, but not to exceed the front member of the solar cell panel.

5. The method for manufacturing the solar cell module according to claim 4, wherein the jig includes a lower projection to abut on the bottom of the main body of the frame, an upper projection to be fitted into the notch and having a shape similar to the upper portion of the fitting part, and a tapered face extending downwardly from a part of the upper projection where the peripheral edge portion of the solar cell panel is positioned toward an edge of the main body of the frame.
